(19) United States
(12) Patent Application Publication
(10) Pub. No.: US 2005/0194649 A1
(43) Pub. Date: Sep. 8, 2005

(54) Semiconductor chip and method for testing semiconductor chip

(76) Inventor: Tomohiro Oki, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/901,377

(22) Filed: Jul. 29, 2004

(30) Foreign Application Priority Data
Feb. 12, 2004 (JP) 2004-34624

(51) Int. Cl. H01L 29/76

(52) U.S. Cl. 257/409

(57) ABSTRACT

A semiconductor chip comprise a semiconductor substrate; circuit elements formed on a surface of the semiconductor substrate; a wiring layer including wiring electrically connected to the circuit elements; an intermediate insulation layer provided between the wiring layer and the semiconductor substrate; a first guard ring provided in the intermediate insulation layer so as to surround a periphery of the circuit elements; a plurality of capacitor electrodes provided at intervals in the intermediate insulation layer and located between the first guard ring and the circuit elements or outside the first guard ring; and a plurality of capacitor pads electrically connected to each of the capacitor electrodes, respectively.

### CROSS-REFERENCE TO RELATED APPLICATIONS

This application is based upon and claims the benefit of priority from the prior Japanese Patent Applications No. 2004-34624, filed on Feb. 12, 2004, the entire contents of which are incorporated herein by reference.

### BACKGROUD OF THE INVENTION

1. Field of the Invention

The present invention relates to a semiconductor chip and a method for testing a semiconductor chip.

2. Related Background Art

In power semiconductor devices, a semiconductor chip having a plurality of probe test pads provided on a guard ring electrode is known to the public (see Japanese Patent Application Laid-Open Publication No. 2002-141474). At the time of test, a resistance value of the guard ring electrode is measured by bringing probe needles into contact with these pads and causing a current to flow through the guard ring electrode. It is determined on the basis of the resistance value whether there is a missing portion in the guard ring electrode.

On the other hand, in the logic LSIs, conventionally aluminum has been used as a material of metal wiring and a silicon oxide film has been used as a material of intermediate insulation layers. At this time, the guard ring is not necessary for the logic LSIs. In recent years, a multilayer wiring structure has come to be used frequently as semiconductor devices are miniaturized. The multilayer wiring structure includes a plurality of metal wiring layers and a plurality of intermediate insulation layers provided between these metal wiring layers. The wiring delay becomes a problem for such a multilayer wiring structure. It is considered to use copper having comparatively low resistance as the material of metal wiring and to use a low dielectric material (hereafter referred to as low-k material) as the material of the intermediate insulation layers in order to prevent the wiring delay.

As compared with the silicon oxide film, however, the low-k material is higher in hygroscopicity. When a semiconductor wafer has undergone dicing, therefore, the low-k material is exposed to the atmosphere at a cutting section of a semiconductor chip, and moisture is absorbed therefrom. If the moisture reaches a logic circuit, it has a bad influence upon the logic circuit. Furthermore, since peeling off is apt to occur between copper and barrier metal (such as Ta, TaN, Ti, TiN, or TiSiN), and the low-k material, the possibility that a gap occurs between the wiring layer and the intermediate insulation layer in the dicing process is high.

In the case where copper is used in the metal wiring layer or in the case where the low-k material is used in the intermediate insulation layers, therefore, it is desirable in the logic LSI as well to form a guard ring on the periphery of the semiconductor chip so as to prevent moisture and peeling off from reaching the logic circuit.

If the logic LSI has a damaged guard ring, the moisture or peeling off reaches the logic circuit in some cases. As a result, there is a possibility that the logic circuit will become defective in a screening test (for example, reliability evaluation such as high temperature leaving as it is) before product shipping.

In the conventional semiconductor chip, however, it cannot be determined whether the defect is caused by a process of the logic circuit or caused by a damage in the guard ring. This results in a problem that a long time is required for the analysis of the semiconductor chip and consequently a huge cost is required.

Furthermore, if the guard ring has damage, then moisture gradually penetrates from the intermediate insulation layers into the logic circuit, and consequently there is a possibility that the logic circuit will become defective after passing a screening test.

In addition, in the conventional semiconductor chip, it cannot be determined to what degree what place in the card ring is damaged.

### SUMMARY OF THE INVENTION

A semiconductor chip according to an embodiment of the present invention comprises a semiconductor substrate; circuit elements formed on a surface of the semiconductor substrate; a wiring layer including wiring electrically connected to the circuit elements; an intermediate insulation layer provided between the wiring layer and the semiconductor substrate; a first guard ring provided in the intermediate insulation layer so as to surround a periphery of the circuit elements; a plurality of capacitor electrodes provided at intervals in the intermediate insulation layer and located between the first guard ring and the circuit elements or outside the first guard ring; and a plurality of capacitor pads electrically connected to each of the capacitor electrodes, respectively.

A semiconductor chip according to another embodiment of the present invention comprises a semiconductor substrate; logic circuit elements formed on a surface of the semiconductor substrate; a wiring layer including wiring electrically connected to the logic circuit elements; an intermediate insulation layer provided between the wiring layers and the semiconductor substrate; a first guard ring provided in the intermediate insulation layer so as to surround a periphery of the logic circuit elements; and a plurality of guard ring pads electrically connected to the first guard ring.

In a method for testing a semiconductor chip according to an embodiment of the present invention, the semiconductor chip includes circuit elements formed on a surface of a semiconductor substrate, a wiring layer including wiring electrically connected to the circuit elements, an intermediate insulation layer provided between the wiring layer and the semiconductor substrate, a first guard ring provided in the intermediate insulation layer so as to surround a periphery of the circuit elements, a plurality of capacitor electrodes provided at intervals in the intermediate insulation layer located between the first guard ring and the circuit elements, and a plurality of capacitor pads electrically connected to each of the capacitor electrodes respectively,
the method for testing a semiconductor chip comprises: bringing probe needles for test into contact with at least two pads included in the plurality of capacitor pads; applying a voltage to the at least two pads via the probe needles and measuring capacitance between the two capacitor electrodes connected to the two pads; and judging on the basis of capacitance between the two capacitor electrodes whether the intermediate insulation layers are or the guard ring is acceptable.

In a method for testing a semiconductor chip according to another embodiment of the present invention, the semiconductor chip includes circuit elements formed on a surface of the semiconductor substrate, a wiring layer including wiring electrically connected to the circuit elements, an intermediate insulation layer provided between the wiring layer and the semiconductor substrate, a guard ring provided in the intermediate insulation layer so as to surround a periphery of the circuit elements, guard ring pads connected to the guard ring, capacitor electrodes provided at intervals in the intermediate insulation layer located between the guard ring and the circuit elements, and capacitor pads electrically connected to the capacitor electrodes, respectively, the method for testing a semiconductor chip comprises: bringing probe needles for test into contact with the guard ring pad and the capacitor pad; applying a voltage to the guard ring pad and the capacitor pad via the probe needles and measuring capacitances between the guard ring and the capacitor electrode; and judging on the basis of capacitances between the guard ring and the capacitor electrode whether the guard ring is acceptable.

### BRIEF DESCRIPTION OF THE DRAWINGS

FIG. 1 is a top view of a semiconductor chip 100 according to a first embodiment of the present invention;

FIG. 2 is a cross-sectional view taken along a line A-A shown in FIG. 1;

FIG. 3 is a cross-sectional view taken along a line B-B shown in FIG. 1;

FIG. 4 is a flow diagram showing a method for testing a semiconductor chip 100;

FIG. 5 is a top view of a semiconductor chip according to a second embodiment of the present invention;

FIG. 6 is a cross-sectional view taken along a line D-D shown in FIG. 5;

FIG. 7 is a top view of a semiconductor chip 300 according to a third embodiment of the present invention;

FIG. 8 is a top view of a semiconductor chip 400 according to a fourth embodiment of the present invention;

FIG. 9 is a top view of a semiconductor chip 500 according to a fifth embodiment of the present invention;

FIG. 10 is a top view of a semiconductor chip 600 according to a sixth embodiment of the present invention; and

FIG. 11 is a cross-sectional view taken along a line C-C shown in FIG. 10.

### DESCRIPTION OF THE INVENTION

Hereafter, embodiments according to the present invention will be described with reference to drawings. These embodiments do not limit the present invention. Semiconductor chips according to these embodiments can judge that the guard ring is damaged and the place of the damage. In the drawings, the same reference numerals denote the same or similar components.

### First Embodiment

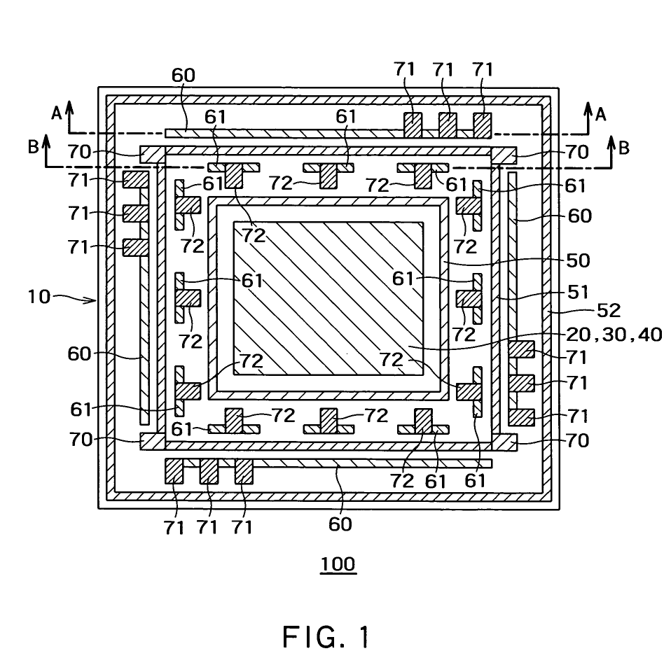

FIG. 1 is a top view of a semiconductor chip 100 according to a first embodiment of the present invention. The semiconductor chip 100 includes a semiconductor substrate 10, circuit elements 20, wiring layers 30, intermediate insulation layers 40, guard rings 50, 51 and 52, capacitor electrodes 60 and 61, and pads 70, 71 and 72. The circuit elements 20 are formed on a surface of the semiconductor substrate 10. The wiring layers 30 including wiring electrically connected to the circuit elements 20 are formed on the circuit elements 20. The semiconductor substrate 10 may be a silicon substrate or a gallium arsenide substrate. The circuit elements 20 may be, for example, logic circuit elements, memory circuit elements, or power semiconductor elements.

Each of the intermediate insulation layers 40 is provided between the wiring layer 30 and the semiconductor substrate 10 or the circuit elements 20. Contact holes or VIA holes are provided through the intermediate insulation layer 40. Wiring is electrically connected to the circuit elements 20 through the contact holes or VIA holes. The intermediate insulation layer 40 insulates between the wiring layer 30 and the semiconductor substrate 10 or the circuit elements 20 in regions other than the contact holes or the VIA holes. The wiring layer 30 may be formed, of aluminum, copper, Al—Si, Al—Si—Cu or tungsten. The intermediate insulation layer 40 is formed of the so-called low-k material. For example, the intermediate insulation layer 40 may be an insulation film formed of a silicon oxide film doped fluorosis (SiOF) or a silicon oxide film doped carbon (SiOC), or may be an insulation film formed of at least one organic coating material selected from a group including resin having a siloxane bond as a main framework, resin having C-C bond as a main framework, and resin having a C═C bond as a main framework. These low-k materials may be porous insulation films.

By alternately repeating deposition and patterning, a multilayer wiring structure (not illustrated) can be formed of the wiring layers 30 and the intermediate insulation layers 40. This multilayer wiring structure need not be especially limited, but may have an arbitrary configuration.

The guard rings 50 to 52 are provided in the intermediate insulation layer 40 so as to surround the periphery of the circuit elements 20. The guard ring 50 is disposed along an outer edge of the circuit elements 20 so as to be somewhat outside the outer edge. The guard ring 52 is disposed along an outer edge of the semiconductor chip 100 so as to be somewhat inside the outer edge. The guard ring 51 is provided between the guard rings 50 and 52. The guard rings 50 to 52 are formed so as to reach a surface 12 of the semiconductor substrate 10 from the highest surface of the intermediate insulation layers 40. The guard rings 50 to 52 can be made of the same material as the wiring layers 30, and can be formed by using the same process as that of the wiring layers 30.

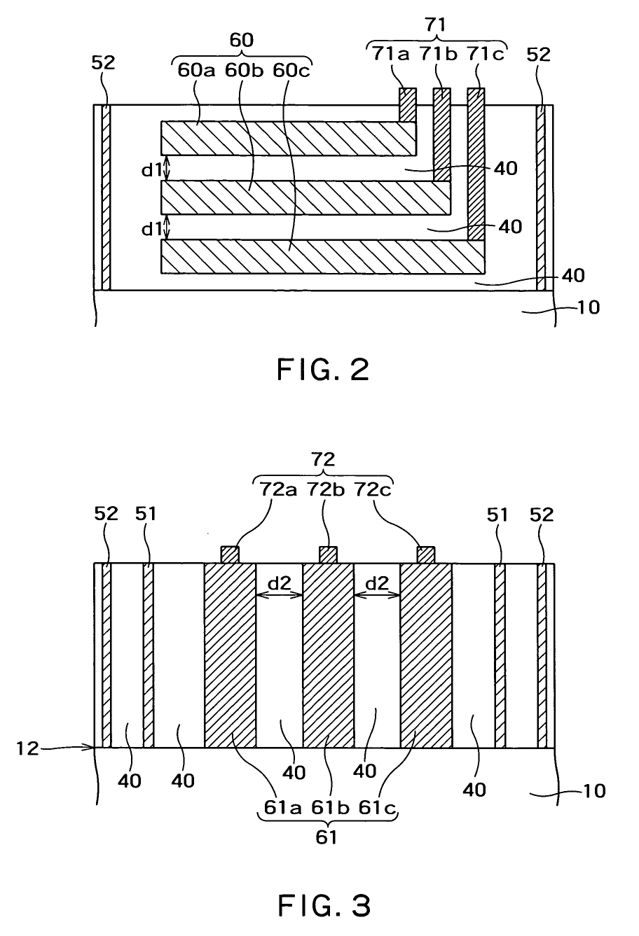

A plurality of capacitor electrodes 61 are disposed between the guard rings 50 and 51. A plurality of capacitor electrodes 60 are disposed between the guard rings 51 and 52. This arrangement of the capacitor electrodes 60 and 61 will be described later with reference to FIGS. 2 and 3. The capacitor electrodes 60 and 61 can be made of the same material as the wiring layers 30, and can be formed by using the same process as that of the wiring layers 30.

Pads 70 are disposed in four corners of the guard ring 51, and electrically connected to the guard ring 51. Pads 71 and 72 are disposed so as to be electrically connected to the capacitor electrodes 60 and 61, respectively. The pads 70 to 72 can be formed of the same material as that of the wiring layers 30, and formed by using the same process as that of the wiring layers 30.

FIG. 2 is a cross-sectional view taken along a line A-A shown in FIG. 1. In this cross-section, three capacitor electrodes 60a, 60b and 60c are provided as the capacitor electrodes 60. The capacitor electrodes 60a, 60b and 60c are arranged in a direction nearly perpendicular to the surface 12 of the semiconductor substrate 10. A gap between the capacitor electrodes 60a and 60b and a gap between the capacitor electrodes 60b and 60c are equal to each other, and are equal to d1. Since the intermediate insulation layers 40 are interposed respectively between the capacitor electrodes 60a and 60b and between the capacitor electrodes 60b and 60c, the capacitor electrodes 60a, 60b and 60c are electrically insulated, respectively. The capacitor electrodes 60a, 60b and 60c are electrically connected to the pads 71a, 71b and 71c, respectively. The capacitor electrodes 60a, 60b and 60c can be formed by using the same process as the multilayer wiring structure forming process.

FIG. 3 is a cross-sectional view taken along a line B-B shown in FIG. 1. In this cross-section, three capacitor electrodes 61a, 61b and 61c are provided as the capacitor electrodes 61. The capacitor electrodes 61a, 61b and 61c are arranged in a direction nearly horizontal to the surface 12 of the semiconductor substrate 10. A gap between the capacitor electrodes 61a and 61b and a gap between the capacitor electrodes 61b and 61c are equal to each other, and are equal to d2. Since the intermediate insulation layers 40 are interposed respectively between the capacitor electrodes 61a and 61b and between the capacitor electrodes 61b and 61c, the capacitor electrodes 61a, 61b and 61c are electrically insulated, respectively. The capacitor electrodes 61a, 61b and 61c are electrically connected to the pads 72a, 72b and 72c, respectively.

Operation of the present embodiment will now be described. When the semiconductor elements 20, the metallic wiring layers 30, the intermediate insulation layers 40 and a protection film are fabricated on the semiconductor substrate 10, the semiconductor wafer is diced to form individual semiconductor chips 100. As a result, cut sections of the semiconductor chips 100 are exposed to the atmosphere, and the intermediate insulation layers 40 begin to absorb moisture. Until the semiconductor chips 100 are sealed by resin, the intermediate insulation layers 40 continue to absorb moisture. Furthermore, in this dicing process, peeling off between the metallic wiring layers 30 and the intermediate insulation layers 40 (hereafter referred to simply as peeling off) occurs in some cases.

First, the guard ring 52 functions to suppress moisture from the outer edge of the semiconductor chip 100 to its inside or to prevent the peeling off. Since the guard ring 52 is formed from the top surface of the intermediate insulation layers 40 to the surface 12 of the semiconductor substrate 10, typically moisture or peeling off can be suppressed by the guard ring 52. In the case where the guard ring 52 is damaged by dicing or the like or has erosion, however, moisture or peeling off penetrates into the inside of the guard ring 52.

Upon reaching the capacitor electrodes 60, the moisture or peeling off changes the dielectric constant of the intermediate insulation layer 40 interposed between the capacitor electrodes 60a and 60b or the intermediate insulation layer 40 interposed between the capacitor electrodes 60b and 60c shown in FIG. 2. By measuring capacitance between the capacitor electrodes 60a and 60b and capacitance between the capacitor electrodes 60b and 60c, therefore, it is found that the moisture or peeling off has penetrated between the guard rings 52 and 51.

In the present embodiment, capacitor electrodes 60 are disposed respectively on four sides of the semiconductor chip 100 as shown in FIG. 1. Therefore, it can be judged on which side the damage or the like of the guard ling 52 has occurred. In addition, since the capacitor electrodes 60a, 60b and 60c are arranged in a direction perpendicular to the surface 12, it can be detected that there is a defect in any of the wiring layers 30 or the intermediate insulation layers 40 in the multilayer wiring structure by measuring capacitance between these electrodes.

Also in the case where the guard ring 51 is damaged by dicing or the like or has erosion, moisture or peeling off penetrates into the inside of the guard ring 51. Upon reaching the capacitor electrodes 61, the moisture or peeling off changes the dielectric constant of the intermediate insulation layer 40 interposed between the capacitor electrodes 61a and 61b shown in FIG. 3 or the intermediate insulation layer 40 interposed between the capacitor electrodes 61b and 61c. By measuring capacitance between the capacitor electrodes 61a and 61b and capacitance between the capacitor electrodes 61b and 61c, therefore, it is found that the moisture or peeling off has penetrated between the guard rings 51 and 50. In addition, since the capacitor electrodes 61 are arranged in parallel in a direction horizontal to the surface 12, a damaged place or a defective layer can be judged in further detail.

In the case where also the guard ring 50 is damaged by dicing or the like or has erosion, moisture or peeling off penetrates into the inside of the guard ring 50. In this case, the circuit elements 20 cause defective operation and consequently the semiconductor chip 100 can be discarded as a defective product.

Thus, according to the present embodiment, a damaged place and a defective layer in the guard rings 50 to 52 can be determined and the degree of penetration of the moisture or peeling off can be detected. As a result, the lifetime of the semiconductor chip in the market can be estimated to some degree. Furthermore, the number of guard rings required to prevent penetration of the moisture or peeling off can be determined.

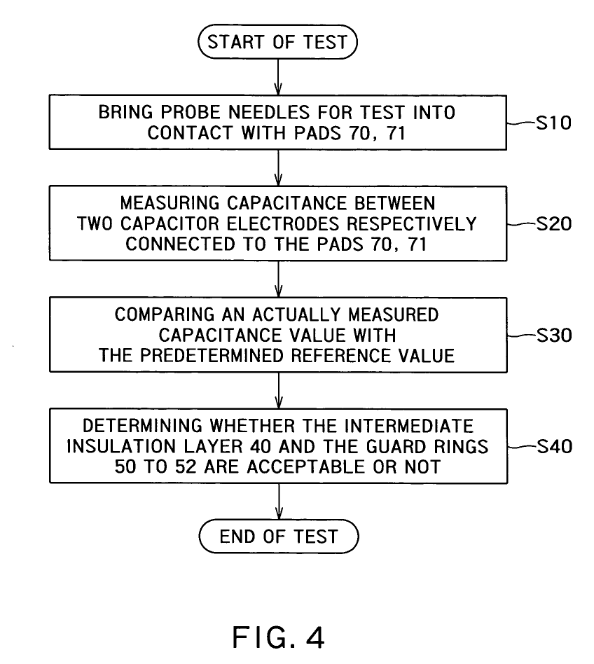

FIG. 4 is a flow diagram showing an example of a method for testing the semiconductor chip 100. First, probe needles for test are brought into contact with at least two pads in the pads 71 (S10). Subsequently, a voltage is applied to the pads 71 via the probe needles, and capacitance between two capacitor electrodes respectively connected to the pads 71 is measured (S20). A preset capacitance value of an acceptable product is taken as a reference value, and an actually measured capacitance value is compared with the reference value (S30). As a result, it can determined on the basis of the capacitance between two capacitor electrodes 60 whether the intermediate insulation layer 40 and the guard rings 50, 51 and 52 are acceptable or not (S40). Consequently, it can be determined whether the intermediate insulation layer 40 between the capacitor electrodes 60 has absorbed moisture or peeling off has occurred. As for the pads 72 as well, it can determined on the basis of the capacitance between two capacitor electrodes 61 by testing the pads 72 in the same way as the pads 71 whether the intermediate insulation layer 40 and the guard ring 50, 51 and 52 are acceptable or not. Consequently, it can be determined whether the intermediate insulation layers 40 between the capacitor electrodes 61 has absorbed moisture or peeling of has occurred.

In addition, capacitance between the pad 71 or 72 and the pad 70 can also be measured by using a method similar to the method shown in FIG. 4. As a result, the capacitance value between the capacitor electrode 60 or 61 and the guard ring 51 can be measured. Consequently, it can be determined in which position of the guard ring 51 a defect has occurred. Specifically, a defect place in the guard ring 51 can be determined in a direction perpendicular to the surface of the semiconductor substrate 10 by measuring the capacitance value between the capacitor electrode 60 and the guard ring 51. In the case where the capacitor electrodes 60 are separately provided so as to correspond to each layer, it can be determined in which layer the guard ring 51 is damaged. By measuring the capacitance value between the capacitor electrode 61 and the guard ring 51, the defect place in the guard ring 51 can be determined in the direction horizontal to the surface of the semiconductor substrate 10. By altering the number and arrangement of the capacitor electrodes 60 and 61 on both side of the guard ring 51, determination precision of the defective place can be improved.

In the present embodiment, the gap between the capacitor electrodes 60a and 60b and the gap between the capacitor electrodes 60b and 60c are equal to each other. As a result, it is sufficient to set one capacitance reference value and comparative arithmetic operation becomes simple. Since the gap between the capacitor electrodes 61a and 61b and the gap between the capacitor electrodes 61b and 61c are also equal to each other, a similar effect is obtained.

In the present embodiment, three guard rings (50 to 52) are provided. However, two or less guard rings or at least four guard rings may also be provided. In some cases, the aptness of the guard rings to be damaged or eroded and peel off depends upon the manufacture line for the semiconductor chip 100. Therefore, it is possible to measure the capacitance between capacitor electrodes of an actual trial product and determine the number of guard rings required to suppress the moisture and peeling off.

So long as the capacitor electrodes 60 and 61 are not in contact with the guard rings 50 to 52, the capacitor electrodes 60 and 61 need to be provided only between the outer edge of the circuit elements 20 and the outer edge of the semiconductor chip 100. Therefore, in the same way as the capacitor electrodes 61 or instead of the capacitor electrodes 61, the capacitor electrodes 60 may be provided in the intermediate insulation layers 40 between the guard ring 50 and the guard ring 51. In the same way as the capacitor electrodes 60 or instead of the capacitor electrodes 60, the capacitor electrodes 61 may be provided in the intermediate insulation layers 40 between the guard ring 51 and the guard ring 52. In addition, the capacitor electrodes 60 and 61 may also be provided in the intermediate insulation layers 40 between the region of the circuit elements 20 and the guard ring 50. The capacitor electrodes 60 and 61 may also be provided in the intermediate insulation layers between the guard ring 52 and the outer edge of the semiconductor chip 100.

Three capacitor electrodes 60 are provided in FIG. 2 and three capacitor electrodes 61 are provided in FIG. 3. However, two or less or at least four capacitor electrodes may also be provided. However, it is desirable that the number of the capacitor electrodes 60 does not exceed the number of the wiring layers 30 in the multilayer wiring structure.

### Second Embodiment

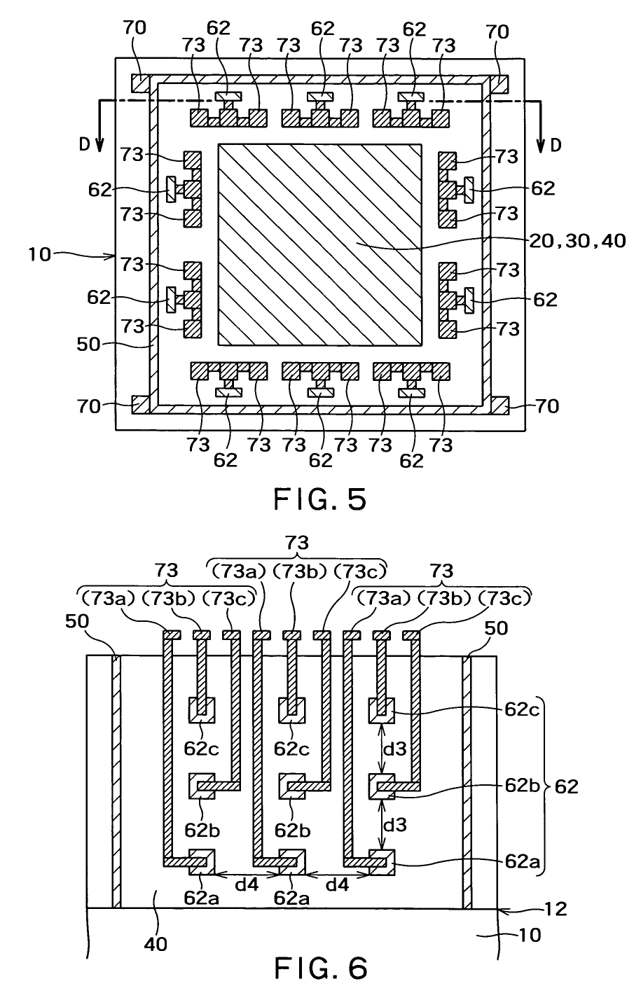

FIG. 5 is a top view of a semiconductor chip 200 according to a second embodiment of the present invention. The semiconductor chip 200 differs from the first embodiment in that the capacitor electrodes 62 are arranged in a matrix form in a cross-section along a line D-D. In the present embodiment, only one guard ring is provided in order to facilitate understanding.

FIG. 6 is a cross-sectional view taken along a line D-D shown in FIG. 5. In this cross-section, three capacitor electrodes 62a, 62b and 62c are provided as the capacitor electrodes 62. The capacitor electrodes 62a, 62b and 62c are arranged in a direction nearly perpendicular to the surface 12. The capacitor electrodes 62 including the capacitor electrodes 62a, 62b and 62c are arranged in a direction nearly horizontal to the surface 12. In other words, the capacitor electrodes 62a, 62b and 62c are arranged in a matrix form in the cross-section.

A gap between the capacitor electrodes 62a and 62b and a gap between the capacitor electrodes 62b and 62c are equal to each other, and are equal to d3. A gap between adjacent capacitor electrodes 62 is equal to d4.

Since the intermediate insulation layers 40 are interposed respectively between the capacitor electrodes 60a and 60b and between the capacitor electrodes 60b and 60c, the capacitor electrodes 60a, 60b and 60c are electrically insulated, respectively.

The capacitor electrodes 62a, 62b and 62c are electrically connected to the pads 73a, 73b and 73c, respectively. The capacitor electrodes 62a, 62b and 62c can be formed by using the same process as the multilayer wiring structure forming process.

In the present embodiment, in a cross-section between the guard ring 50 and the circuit elements 20, the capacitor electrodes 62a, 62b and 62c are arranged in a matrix form as shown in FIG. 6. As a result, the moisture or peeling off changes the dielectric constant of the intermediate insulation layers 40 interposed between the capacitor electrodes 62a and 62b, the intermediate insulation layer 40 interposed between the capacitor electrodes 62b and 62c, or the intermediate insulation layer 40 between adjacent capacitor electrodes 62. By measuring capacitance between the capacitor electrodes 62a and 62b, capacitance between the capacitor electrodes 62b and 62c, or capacitance between adjacent capacitor electrodes 62, therefore, it is found that the moisture or peeling off has penetrated between the guard ring 50 and the circuit elements 20.

The arrangement gap between the capacitor electrodes 62a and 62b and the arrangement gap between the capacitor electrodes 62b and 62c are equal to each other, and are equal to d3. The gaps between adjacent capacitor electrodes 62 are equal to each other, and are equal to d4. As a result, it is sufficient to set two capacitance reference values (i.e., capacitance values of acceptable products). Consequently, comparative arithmetic operation becomes simple. The gap d3 may be equal to the gap d4. In this case, it is sufficient to set one capacitance reference value, and comparative arithmetic operation becomes further simple.

In the first embodiment, both the capacitor electrodes 60 and 61 are required to measure the capacitance of the intermediate insulation layers 40 longitudinally and laterally with respect to the surface 12. In the second embodiment, however, the capacitor electrodes 62 are arranged in a matrix form and consequently the capacitance of the intermediate insulation layers 40 can be measured longitudinally and laterally with respect to the surface 12 by using only the capacitor electrodes 62. As a result, the second embodiment can be made smaller in chip area than the first embodiment. In addition, the present embodiment has the same effects as those of the first embodiment.

In the present embodiment, capacitance between the pad 70 and the pad 73 can also be measured by using a method similar to the method shown in FIG. 4. As a result, the capacitance value between the capacitor electrode 62 and the guard ring 50 can be measured. Consequently, it can be determined in which position of the guard ring 50 a defect has occurred. Since the capacitor electrodes 62 are arranged in a plane perpendicular to the plane of the semiconductor substrate 10 in a matrix form, it can be determined in which layer the guard ring 51 is damaged or in which plane position the guard ring 51 is damaged, on the basis of the capacitance value between the capacitor electrode 62 and the guard ring 50. By altering the number and arrangement of the capacitor electrodes 62, determination precision of the defective place can be improved. Furthermore, by disposing the capacitor electrodes 62 on both side of the guard ring 50, determination precision of the defective place can be improved.

Subsequently, third to sixth embodiments will now be described. In the first and second embodiments, penetration of moisture into the intermediate insulation layers 40 or degree of peeling off of the intermediate insulation layers 40 is detected by measuring the capacitance value of the intermediate insulation layers. In the third to sixth embodiments, however, the penetration of the moisture into the intermediate insulation layers 40 or the degree of peeling off of the intermediate insulation layers 40 is detected by measuring the resistance value of the intermediate insulation layers.

### Third Embodiment

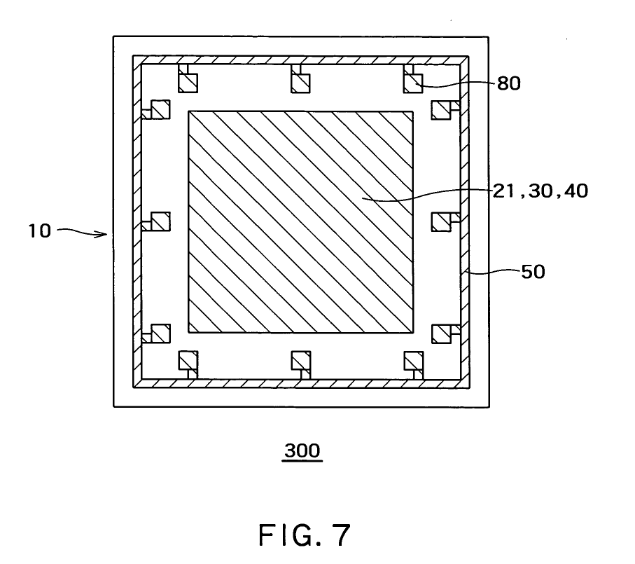

FIG. 7 is a top view of a semiconductor chip 300 according to a third embodiment of the present invention. The semiconductor chip 300 includes a semiconductor substrate 10, a logic circuit 21, wiring layers 30, intermediate insulation layers 40, a guard ring 50 and pads 80. The wiring layers 30 including electrically connected wiring electrically connected to the logic circuit 21 are formed on the logic circuit 21.

Between the wiring layer 30 and the semiconductor substrate 10 or the logic circuit 21, the intermediate insulation layer 40 is provided. Contact holes are provided through the intermediate insulation layer 40. Wiring is electrically connected to the logic circuit 21 through the contact holes. The intermediate insulation layers 40 insulate between the wiring layer 30 and the semiconductor substrate 10 or the logic circuit 21 in regions other than the contact holes.

The guard ring 50 is provided in the intermediate insulation layers 40 so as to surround the periphery of the logic circuit 21. The guard ring 50 is disposed along an outer edge of the logic circuit 21 or an outer edge of the semiconductor chip 100.

A plurality of pads 80 are disposed between the guard ring 50 and the logic circuit 21. The pads 80 are connected to different places in the guard ring 50. The pads 80 can be made of the same material as the wiring layers 30, and can be formed by using the same process as that of the wiring layers 30.

According to the present embodiment, damage in the guard ring 50 can be detected by measuring the resistance value between different pads among the pads 80, even in the logic LSI using the low-k material in the intermediate insulation layers. By providing a large number of pads 80, the damaged place in the guard ring 50 can be determined.

### Fourth Embodiment

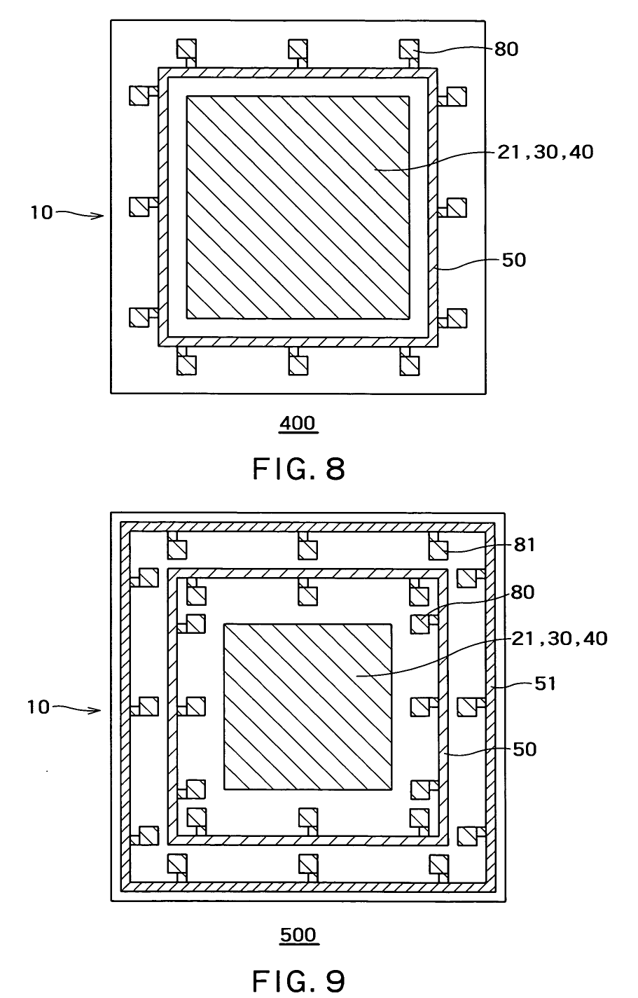

FIG. 8 is a top view of a semiconductor chip 400 according to a fourth embodiment of the present invention. The semiconductor chip 400 differs from the semiconductor chip 300 in that a plurality of pads 80 are arranged between the guard ring 50 and an outer edge of the semiconductor chip 400. Other components may be the same as those of the semiconductor chip 300. The present embodiment has effects similar to those of the third embodiment.

### Fifth Embodiment

FIG. 9 is a top view of a semiconductor chip 500 according to a fifth embodiment of the present invention. The semiconductor chip 500 differs from the semiconductor chip 300 in that a plurality of guard rings are provided. Other components may be the same as those of the semiconductor chip 300. A guard ring 51 is provided near an outer edge of the semiconductor chip 500. The guard ring 50 is provided between the logic circuit 21 and the guard ring 51. A plurality of pads 81 are electrically connected to the guard ring 51.

The present embodiment has effects similar to those of the third embodiment. In addition, according to the present embodiment, in the case where the semiconductor chip 500 is damaged in the dicing process, the degree of the damage can be detected by measuring resistance values of the guard rings 50 and 51. If intermediate layers 40 have absorbed moisture from an outer edge of the semiconductor chip 500, the guard ring 50 or 51 is eroded by the moisture. Therefore, the degree of penetration of the moisture can be detected by measuring the resistance value of the guard rings 50 and 51.

### Sixth Embodiment

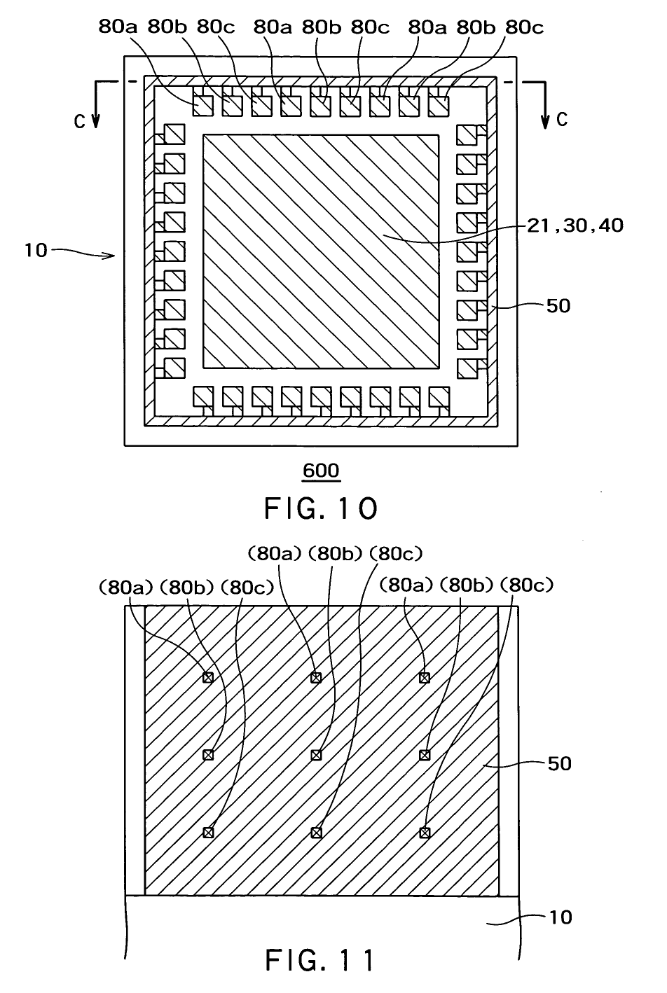

FIG. 10 is a top view of a semiconductor chip 600 according to a sixth embodiment of the present invention. FIG. 11 is a cross-sectional view taken along a line C-C shown in FIG. 10. The semiconductor chip 600 differs from the semiconductor chip 300 in that a plurality of guard rings 80a, 80b and 80c are respectively connected to the positions in the guard ring 50 having different heights from the surface 12 of the semiconductor substrate 10. In other words, the connection nodes of the pads 80a, 80b and 80c are arranged in a matrix form in the cross-section. Other components may be the same as those of the semiconductor chip 300.

The present embodiment has effects similar to those of the third embodiment. In addition, according to the present embodiment, a damaged place and a defective layer in the guard ring 50 can be determined by measuring resistance values between pads.

1. A semiconductor chip comprising:
a semiconductor substrate;
circuit elements formed on a surface of the semiconductor substrate;
a wiring layer including wiring electrically connected to the circuit elements;
an intermediate insulation layer provided between the wiring layer and the semiconductor substrate;
a first guard ring provided in the intermediate insulation layer so as to surround a periphery of the circuit elements;
a plurality of capacitor electrodes provided at intervals in the intermediate insulation layer and located between the first guard ring and the circuit elements or outside the first guard ring; and
a plurality of capacitor pads electrically connected to each of the capacitor electrodes, respectively.

2. The semiconductor chip according to claim 1 wherein,
the plurality of capacitor electrodes are arranged in a direction nearly perpendicular to the surface of the semiconductor substrate.

3. The semiconductor chip according to claim 1 wherein,
the plurality of capacitor electrodes are arranged in a direction nearly horizontal to the surface of the semiconductor substrate.

4. The semiconductor chip according to claim 1 wherein,
the plurality of capacitor electrodes are arranged in a matrix form in a direction nearly horizontal and perpendicular to the surface of the semiconductor substrate.

5. The semiconductor chip according to claim 2 wherein,
the plurality of capacitor electrodes are arranged at constant intervals in a direction nearly perpendicular to the surface of the semiconductor substrate.

6. The semiconductor chip according to claim 3 wherein,
the plurality of capacitor electrodes are arranged at constant intervals in a direction nearly horizontal to the surface of the semiconductor substrate.

7. The semiconductor chip according to claim 4 wherein,
the plurality of capacitor electrodes are arranged at constant intervals in a matrix form in a direction nearly horizontal and perpendicular to the surface of the semiconductor substrate.

8. The semiconductor chip according to claim 4 wherein,
a plurality of guard ring pads are electrically connected to the first guard ring, respectively.

9. The semiconductor chip according to claim 1 wherein,
the intermediate insulation layer is composed of a low-k material.

10. The semiconductor chip according to claim 1 further comprising:
a second guard ring provided between the circuit elements and the first guard ring; wherein,
the first guard ring is provided near an outer edge of the semiconductor chip.

11. The semiconductor chip according to claim 1, wherein
the wiring is formed in a multilayer wiring structure,
the first guard ring is formed so as to reach a surface of the semiconductor substrate from a top surface of the intermediate insulation layer.

12. The semiconductor chip according to claim 11, wherein
the plurality of guard ring pads are connected electrically to positions in the first guard ring, said positions being different in height from the surface of the semiconductor substrate.

13. The semiconductor chip according to claim 12, wherein
the connecting positions between the plurality of the guard ring pads and the first guard ring are provided at constant intervals.

14. A semiconductor chip comprising:
a semiconductor substrate;
logic circuit elements formed on a surface of the semiconductor substrate;
a wiring layer including wiring electrically connected to the logic circuit elements;
an intermediate insulation layer provided between the wiring layers and the semiconductor substrate;
a first guard ring provided in the intermediate insulation layer so as to surround a periphery of the logic circuit elements; and
a plurality of guard ring pads electrically connected to the first guard ring.

15. The semiconductor chip according to claim 14 wherein,
the intermediate insulation layer is composed of a low-k material.

16. The semiconductor chip according to claim 14 further comprising:
a second guard ring provided between the logic circuit elements and the first guard ring; wherein,
the first guard ring is provided near an outer edge of the semiconductor chip.

17. The semiconductor chip according to claim 14, wherein
the wiring is formed in a multilayer wiring structure,
the first guard ring is formed so as to reach a surface of the semiconductor substrate from a top surface of the intermediate insulation layer.

18. The semiconductor chip according to claim 17, wherein
the plurality of guard ring pads are connected electrically to positions in the first guard ring, said positions being different in height from the surface of the semiconductor substrate.

19. A method for testing a semiconductor chip including circuit elements formed on a surface of a semiconductor substrate, a wiring layer including wiring electrically connected to the circuit elements, an intermediate insulation layer provided between the wiring layer and the semiconductor substrate, a first guard ring provided in the intermediate insulation layer so as to surround a periphery of the circuit elements, a plurality of capacitor electrodes provided at intervals in the intermediate insulation layer located between the first guard ring and the circuit elements, and a plurality of capacitor pads electrically connected to each of the plurality of capacitor electrodes respectively,
the method for testing a semiconductor chip comprising:
bringing probe needles for test into contact with at least two pads included in the plurality of capacitor pads;
applying a voltage to the at least two pads via the probe needles and measuring capacitance between the two capacitor electrodes connected to the two pads; and
judging on the basis of capacitance between the two capacitor electrodes whether the intermediate insulation layers are or the guard ring is acceptable.

20. A method for testing a semiconductor chip including circuit elements formed on a surface of the semiconductor substrate, a wiring layer including wiring electrically connected to the circuit elements, an intermediate insulation layer provided between the wiring layer and the semiconductor substrate, a guard ring provided in the intermediate insulation layer so as to surround a periphery of the circuit elements, guard ring pads connected to the guard ring, capacitor electrodes provided at intervals in the intermediate insulation layer located between the guard ring and the circuit elements, and capacitor pads electrically connected to the capacitor electrodes, respectively, the method for testing a semiconductor chip comprising:
bringing probe needles for test into contact with the guard ring pad and the capacitor pad;
applying a voltage to the guard ring pad and the capacitor pad via the probe needles and measuring capacitances between the guard ring and the capacitor electrode; and
judging on the basis of capacitances between the guard ring and the capacitor electrode whether the guard ring is acceptable.
